(19) United States
(12) Patent Application Publication
(10) Pub. No.: US 2022/0139683 A1
(43) Pub. Date: May 5, 2022

(54) APPARATUS FOR CONTROLLING IMPEDANCE AND SYSTEM FOR TREATING SUBSTRATE WITH THE APPARATUS

(71) Applicant: SEMES Co., Ltd., Chungcheongnam-do (KR)

(72) Inventors: Hyo Seong Seong, Gyeongsangnam-do (KR); Tae Hoon Jo, Seoul (KR); Jeong Yeon Hwang, Gyeonggi-do (KR); Jae Hong Min, Seoul (KR)

(21) Appl. No.: 17/509,200

(22) Filed: Oct. 25, 2021

(30) Foreign Application Priority Data
Oct. 30, 2020 (KR) 10-2020-0142816

(51) Int. Cl. H01J 37/32

(52) U.S. Cl. CPC H01J 37/32935; H01J 37/32642

(57) ABSTRACT

Provided are an impedance control apparatus for automatically compensating impedance by predicting the occurrence of wear on a ring assembly, and a substrate treating system having the same. The substrate treating system includes a housing for providing a space for treating a substrate, a substrate support member installed inside the housing and for supporting the substrate, a plasma generating unit for generating plasma inside the housing, a ring assembly disposed in circumference of the substrate, and an impedance control unit for controlling the impedance around the ring assembly and automatically compensating the impedance by predicting the occurrence of wear of the ring assembly.

### CROSS REFERENCE TO RELATED APPLICATION

This application claims the benefit of Korean Patent Application No. 10-2020-0142816, filed on Oct. 30, 2020, in the Korean Intellectual Property Office, the disclosure of which is incorporated herein by reference in its entirety.

### FIELD OF THE INVENTION

The present invention relates to an impedance control apparatus and a substrate treating system having the same. More particularly, it relates to an impedance control apparatus applied to equipment for performing an etching process, and a substrate treating system having the same.

### BACKGROUND

The process of manufacturing a semiconductor device may be continuously performed in a semiconductor manufacturing facility, and may be divided into a pre-process and a post-process. A semiconductor manufacturing facility may be installed in a space generally defined as a FAB for manufacturing semiconductor devices.

The pre-process refers to a process of forming a circuit pattern on a wafer to complete a chip. The pre-process may include a deposition process for forming a thin film on a wafer, a photo-lithography process for transferring a photo resist onto a thin film using a photo mask, an etching process for selectively removing unnecessary parts using chemical substances or reactive gases to form a circuit pattern on a wafer, an ashing process for removing the photo resist remaining after etching, an ion implantation process for implanting ions into the portion connected to the circuit pattern to have characteristics of an electronic device, a cleaning process for removing contamination sources from the wafer, and the like.

The post-process refers to the process of evaluating the performance of the product finished through the pre-process. The post-process may include a wafer inspection process that checks whether each chip on the wafer operates and selects good and bad products, a package process that cuts and separates each chip through dicing, die bonding, wire bonding, molding and marking to have the shape of the product, and the final inspection process that finally checks the product characteristics and reliability through electrical property inspection, and burn-in inspection.

### SUMMARY OF THE INVENTION

A process of manufacturing a semiconductor device may include a process of treating a substrate using plasma. For example, the etching process may remove the thin film on the substrate using plasma.

However, in order to increase process uniformity, it is necessary to expand the plasma region to the edge region of the substrate. To this end, a ring member capable of generating an electric field coupling effect may be provided to surround the substrate support, and a ring-shaped insulator may be added to electrically isolate it from the lower module of the equipment.

However, as the operating time of the etching equipment increases, the insulator ring may be worn by ions accelerated through the plasma sheath, which may affect the etching profile for the edge region of the substrate.

An aspect of the present invention is an impedance control apparatus for automatically compensating impedance by predicting occurrence of wear on a ring assembly, and a substrate treating system having the same.

The aspects of the present invention are not limited to the aspects mentioned above, and other aspects not mentioned will be clearly understood by those skilled in the art from the following description.

One aspect of the substrate treating system of the present invention for achieving the above object comprises a housing for providing a space for treating a substrate; a substrate support member installed inside the housing and for supporting the substrate; a plasma generating unit for generating plasma inside the housing; a ring assembly disposed in circumference of the substrate; and an impedance control unit for controlling an impedance around the ring assembly and automatically compensating the impedance by predicting occurrence of wear of the ring assembly.

Wherein the impedance control unit may control the impedance based on at least one of a first correlation between a measured voltage around the ring assembly and an ion incident angle around the ring assembly according to a substrate treating time, a second correlation between the measured voltage and the impedance, and a third correlation between the ion incident angle and the impedance.

Wherein the impedance control unit may derive the third correlation based on the first correlation and the second correlation.

Wherein the impedance control unit may generate a first relational expression for calculating the ion incidence angle by calculating the measured voltage, a first variable, and a second variable when the impedance is controlled based on the first correlation.

Wherein the impedance control unit may calculate a value proportional to the measured voltage as the ion incident angle by using the first relational expression.

Wherein the first relational expression may be a linear function.

Wherein the impedance control unit may generate a second relational expression for calculating the impedance by calculating the measured voltage, a third variable, and a fourth variable when the impedance is controlled based on the second correlation.

Wherein the impedance control unit may calculate a value inversely proportional to the measured voltage as the impedance by using the second relational expression.

Wherein the second relational expression may be an exponential function.

Wherein the impedance control unit may control the impedance by using a lookup table generated based on a substrate treating time.

Wherein the impedance control unit may generate the lookup table based on at least two components of a measured voltage around the ring assembly, an ion incident angle around the ring assembly, and the impedance according to the substrate treating time.

Wherein the impedance control unit may repeatedly control the impedance based on a comparison result between a substrate treating time and a reference time.

Wherein a reference time used for a first impedance control may be longer than a reference time used for a second impedance control performed after the first impedance control.

The substrate treating system further comprises a first ring member including a metal component and installed under the ring assembly; a second ring member including an insulator component and installed under the first ring member and the ring assembly; and an insert including a conductive material and inserted into the inside of the second ring member, wherein the impedance control unit is electrically connected to the insert.

Another aspect of the substrate treating system of the present invention for achieving the above object comprises a housing for providing a space for treating a substrate; a substrate support member installed inside the housing and for supporting the substrate; a plasma generating unit for generating plasma inside the housing; a ring assembly disposed in circumference of the substrate; and an impedance control unit for controlling an impedance around the ring assembly, and automatically compensating the impedance based on at least one of a first correlation between a measured voltage around the ring assembly and an ion incident angle around the ring assembly according to a substrate treating time, a second correlation between the measured voltage and the impedance, and a third correlation between the ion incident angle and the impedance.

One aspect of an impedance controlling apparatus of the present invention for achieving the above object, wherein the apparatus controls an impedance around a ring assembly disposed in circumference of a substrate when treating the substrate, comprises a first relational expression generating module for generating a first relational expression based on a first correlation between a measured voltage around the ring assembly and an ion incident angle around the ring assembly according to a substrate treating time; a second relational expression generating module for generating a second relational expression based on a second correlation between the measured voltage and the impedance; and an impedance control module for controlling the impedance based on the first relational expression and the second relational expression.

Wherein the impedance control module may automatically compensate the impedance by predicting occurrence of wear of the ring assembly.

Wherein the first relational expression generating module may generate the first relational expression to calculate the ion incident angle by calculating the measured voltage, a first variable, and a second variable.

Wherein the second relational expression generating module may generate the second relational expression to calculate the impedance by calculating the measured voltage, a third variable, and a fourth variable.

Wherein the impedance control module may control the impedance by using a lookup table generated based on the first relational expression and the second relational expression.

The details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view schematically illustrating a structure of a substrate treating system according to an embodiment of the present invention;

FIG. 2 is a cross-sectional view schematically illustrating a structure of a substrate treating system according to another embodiment of the present invention;

FIG. 3 is a partially enlarged view of a substrate treating system according to various embodiments of the present invention;

FIG. 4 is a block diagram schematically illustrating an internal configuration of an impedance control unit constituting a substrate treating system according to various embodiments of the present invention;

FIG. 5 is an exemplary diagram for describing the function of the first relational expression generating module constituting the impedance control unit shown in FIG. 4;

FIG. 6 is an exemplary diagram for describing the function of the second relational expression generating module constituting the impedance control unit shown in FIG. 4;

FIG. 7 is an exemplary view for describing the function of the impedance control module constituting the impedance control unit shown in FIG. 4;

FIG. 8 is a flowchart illustrating an operation method of an impedance control unit constituting a substrate treating system according to an embodiment of the present invention; and

FIG. 9 is an exemplary diagram illustrating an operation method of an impedance control unit constituting a substrate treating system according to an embodiment of the present invention.

### DETAILED DESCRIPTION OF THE INVENTION

Hereinafter, preferred embodiments of the present invention will be described in detail with reference to the accompanying drawings. Advantages and features of the present invention, and methods for achieving them will be clarified with reference to embodiments described below in detail together with the accompanying drawings. However, the present invention is not limited to the embodiments disclosed below, but may be implemented in various different forms, and only the embodiments allow the publication of the present invention to be complete, and are provided to fully inform those skilled in the technical field to which the present invention pertains of the scope of the invention, and the invention is only defined by the scope of the claims. The same reference numerals refer to the same elements throughout the specification.

When elements or layers are referred to as “on” or “above” of other elements or layers, it includes not only when directly above of the other elements or layers, but also other elements or layers intervened in the middle. On the other hand, when elements are referred to as “directly on” or “directly above,” it indicates that no other element or layer is intervened therebetween.

The spatially relative terms “below,” “beneath,” “lower,” “above,” “upper,” etc., as shown in figures, can be used to easily describe the correlation of components or elements with other components or elements. The spatially relative terms should be understood as terms including the different direction of the element in use or operation in addition to the direction shown in the figure. For example, if the element shown in the figure is turned over, an element described as “below” or “beneath” the other element may be placed “above” the other element. Accordingly, the exemplary term “below” can include both the directions of below and above. The element can also be oriented in other directions, so that spatially relative terms can be interpreted according to the orientation.

Although the first, second, etc. are used to describe various components, elements and/or sections, these components, elements and/or sections are not limited by these terms. These terms are only used to distinguish one component, element, or section from another component, element or section. Therefore, first component, the first element or first section mentioned below may be a second component, second element, or second section within the technical spirit of the present invention.

The terminology used herein is for describing the embodiments and is not intended to limit the present invention. In the present specification, the singular form also includes the plural form unless otherwise specified in the phrase. As used herein, “comprises” and/or “comprising” means that the elements, steps, operations and/or components mentioned above do not exclude the presence or additions of one or more other elements, steps, operations and/or components.

Unless otherwise defined, all terms (including technical and scientific terms) used in the present description may be used with meanings that can be commonly understood by those of ordinary skill in the art to which the present invention belongs. In addition, terms defined in a commonly used dictionary are not interpreted ideally or excessively unless explicitly defined specifically.

Hereinafter, exemplary embodiments of the present invention will be described in detail with reference to the accompanying drawings, and in the description with reference to the accompanying drawings, the same or corresponding elements are assigned the same reference numbers regardless of reference numerals, and the description overlapped therewith will be omitted.

The present invention relates to an impedance control apparatus for automatically compensating an impedance by predicting the occurrence of wear on a ring assembly, and a substrate treating system having the same. According to the present invention, it is possible to prevent or delay the wear of the ring assembly, and thus, it is possible to obtain an effect of improving the etching efficiency of the substrate. Hereinafter, the present invention will be described in detail with reference to drawings and the like.

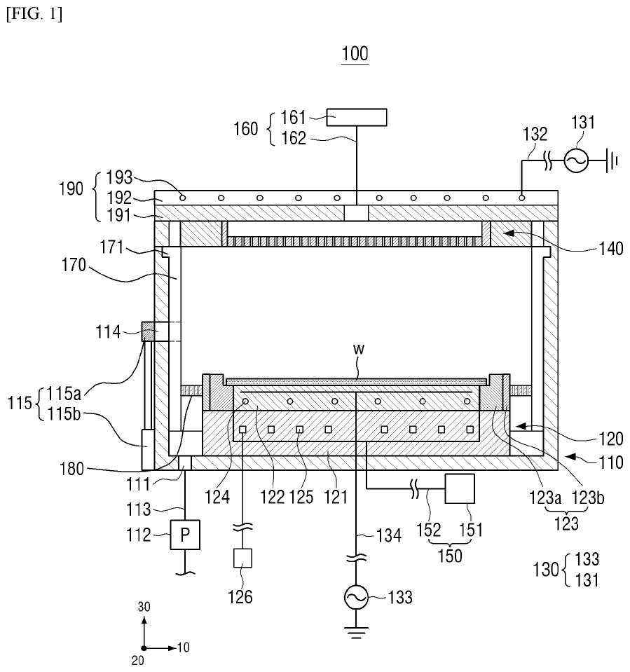

FIG. 1 is a cross-sectional view schematically illustrating a structure of a substrate treating system according to an embodiment of the present invention.

Referring to FIG. 1, a substrate treating system 100 may comprise a housing 110, a substrate support unit 120, a plasma generating unit 130, a shower head unit 140, a first gas supply unit 150, a second gas supply unit, a liner unit 170, a baffle unit 180, and an upper module 190.

The substrate treating system 100 is a system for treating a substrate W (e.g., a wafer) using a dry etching process in a vacuum environment. The substrate treating system 100 may treat the substrate W using, for example, a plasma process.

The housing 110 provides a space, in which the plasma process is performed. The housing 110 may have an exhaust hole 111 at a lower portion thereof.

The exhaust hole 111 may be connected to the exhaust line 113, on which the pump 112 is mounted. The exhaust hole 111 may discharge a reaction-by-product generated during a plasma process and a gas remaining in the housing 110 to the outside of the housing 110 through the exhaust line 113. In this case, the internal space of the housing 110 may be decompressed to a predetermined pressure.

The housing 110 may have an opening 114 formed in a sidewall thereof. The opening 114 may function as a passage, through which the substrate W enters and exits the housing 110. The opening 114 may be configured to be opened and closed by the door assembly 115.

The door assembly 115 may include an outer door 115a and a door driving unit 115b. The outer door 115a is provided on the outer wall of the housing 110. The outer door 115a may be moved in the vertical direction (i.e., the third direction 30) through the door driving unit 115b. The door driving unit 115b may be operated using a motor, a hydraulic cylinder, a pneumatic cylinder, or the like.

The substrate support unit 120 is installed in the inner lower region of the housing 110. The substrate support unit 120 may support the substrate W using an electrostatic force. However, the present embodiment is not limited thereto. The substrate support unit 120 may support the substrate W in various ways such as mechanical clamping, vacuum, and the like.

When the substrate W is supported by using an electrostatic force, the substrate support unit 120 may include a base 121 and an electro-static chuck (ESC) 122.

The electro-static chuck 122 is a substrate support member that supports the substrate W seated thereon by using an electrostatic force. The electro-static chuck 122 may be made of a ceramic material, and may be coupled to the base 121 to be fixed on the base 121.

The electro-static chuck 122 may be installed to be movable in the vertical direction (i.e., the third direction 30) inside the housing 110 using a driving member (not shown). When the electro-static chuck 122 is formed to be movable in the vertical direction as described above, it may be possible to locate the substrate W in a region showing a more uniform plasma distribution.

The ring assembly 123 is provided to surround the edge of the electro-static chuck 122. The ring assembly 123 may be provided in a ring shape to support the edge region of the substrate W. The ring assembly 123 may include a focus ring 123a and an insulator ring 123b.

The focus ring 123a is formed inside the insulator ring 123b and is provided to surround the electro-static chuck 122. The focus ring 123a may be made of a silicon material, and may concentrate ions generated during a plasma process on the substrate W.

The insulator ring 123b is formed outside the focus ring 123a and is provided to surround the focus ring 123a. The insulator ring 123b may be made of a quartz material.

Meanwhile, the ring assembly 123 may further include an edge ring (not shown) formed in close contact with the edge of the focus ring 123a. The edge ring may be formed to prevent the side surface of the electro-static chuck 122 from being damaged by the plasma.

The first gas supply unit 150 supplies the first gas to remove foreign substances remaining on the upper portion of the ring assembly 123 or the edge portion of the electro-static chuck 122. The first gas supply unit 150 may include a first gas supply source 151 and a first gas supply line 152.

The first gas supply source 151 may supply nitrogen gas (N2 Gas) as the first gas. However, the present embodiment is not limited thereto. The first gas supply source 151 may supply other gases, cleaning agents, or the like.

The first gas supply line 152 is provided between the electro-static chuck 122 and the ring assembly 123. The first gas supply line 152 may be formed to be connected between, for example, the electro-static chuck 122 and the focus ring 123a.

Meanwhile, the first gas supply line 152 may be provided inside the focus ring 123a and bent to be connected between the electro-static chuck 122 and the focus ring 123a.

The heating member 124 and the cooling member 125 are provided so that the substrate W can maintain the process temperature while the etching process is in progress inside the housing 110. The heating member 124 may be provided as a heating wire for this purpose, and the cooling member 125 may be provided as a cooling line, through which a refrigerant flows, for this purpose.

The heating member 124 and the cooling member 125 may be installed inside the substrate support unit 120 to allow the substrate W to maintain a process temperature. For example, the heating member 124 may be installed inside the electro-static chuck 122, and the cooling member 125 may be installed inside the base 121.

On the other hand, the cooling member 125 may be supplied with a refrigerant using a chiller 126. The chiller 126 may be installed outside the housing 110.

The plasma generating unit 130 generates plasma from the gas remaining in the discharge space. Here, the discharge space refers to a space located above the substrate support unit 120 in the inner space of the housing 110.

The plasma generating unit 130 may generate plasma in the discharge space inside the housing 110 using an inductively coupled plasma (ICP) source. In this case, the plasma generating unit 130 may use an antenna unit 193 installed in the upper module 190 as an upper electrode and use the electro-static chuck 122 as a lower electrode.

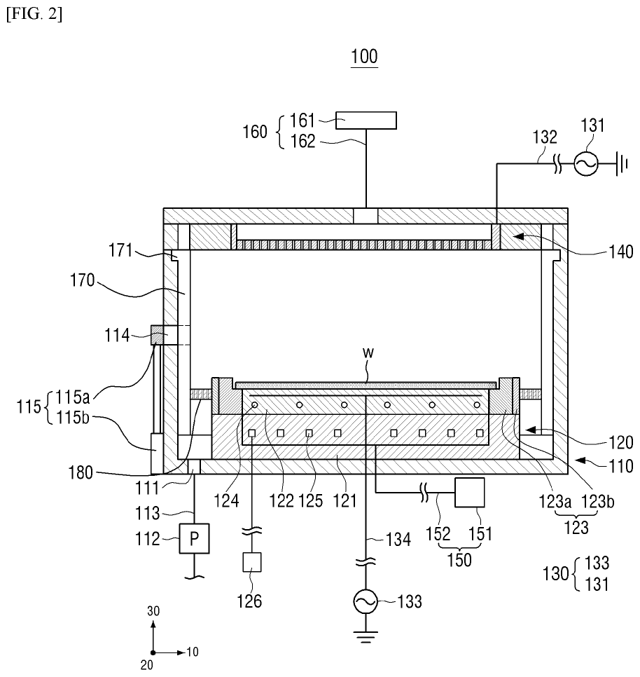

However, the present embodiment is not limited thereto. The plasma generating unit 130 may generate plasma in the discharge space inside the housing 110 using a capacitively coupled plasma (CCP) source. In this case, the plasma generating unit 130 may use the shower head unit 140 as an upper electrode and use the electro-static chuck 122 as a lower electrode as shown in FIG. 2. FIG. 2 is a cross-sectional view schematically illustrating a structure of a substrate treating system according to another embodiment of the present invention.

It will be described again with reference to FIG. 1.

The plasma generating unit 130 may include an upper electrode, a lower electrode, an upper power source 131, and a lower power source 133.

The upper power source 131 applies electric power to the upper electrode, that is, the antenna unit 193. The upper power source 131 may be provided to control plasma characteristics. The upper power source 131 may be provided to adjust, for example, ion bombardment energy.

Although a single upper power source 131 is illustrated in FIG. 1, a plurality of upper power sources 131 may be provided in the present embodiment. When a plurality of upper power sources 131 are provided, the substrate treating system 100 may further include a first matching network (not shown) electrically connected to the plurality of upper power sources.

The first matching network may match and apply frequency powers of different magnitudes input from respective upper power sources to the antenna unit 193.

Meanwhile, on the first transmission line 132 connecting the upper power source 131 and the antenna unit 193, a first impedance matching circuit (not shown) may be provided for the purpose of impedance matching.

The first impedance matching circuit may operate as a lossless passive circuit to effectively (i.e., maximally) transfer electric energy from the upper power source 131 to the antenna unit 193.

The lower power source 133 applies electric power to the lower electrode, that is, the electro-static chuck 122. The lower power source 133 may serve as a plasma source for generating plasma, or may serve to control characteristics of plasma together with the upper power source 131.

Although a single lower power source 133 is illustrated in FIG. 1, a plurality of lower power sources 133 may be provided in the present embodiment like the upper power source 131. When a plurality of lower power sources 133 are provided, a second matching network (not shown) electrically connected to the plurality of lower power sources may be further included.

The second matching network may match and apply frequency powers of different magnitudes input from respective lower power sources to the electro-static chuck 122.

Meanwhile, a second impedance matching circuit (not shown) may be provided on the second transmission line 134 connecting the lower power source 133 and the electro-static chuck 122 for the purpose of impedance matching.

Like the first impedance matching circuit, the second impedance matching circuit may operate as a lossless passive circuit to effectively (i.e., maximally) transfer electric energy from the lower power source 133 to the electro-static chuck 122.

The shower head unit 140 may be installed to face the electro-static chuck 122 in a vertical direction inside the housing 110. The shower head unit 140 may include a plurality of gas feeding holes to feed gas into the housing 110, and may be provided to have a larger diameter than the electro-static chuck 122. Meanwhile, the shower head unit 140 may be made of a silicon material or a metal material.

The second gas supply unit 160 supplies a process gas (second gas) to the inside of the housing 110 through the shower head unit 140. The second gas supply unit 160 may include a second gas supply source 161 and a second gas supply line 162.

The second gas supply source 161 supplies a cleaning gas used to treat the substrate W and the inside of the housing 110 as a process gas. The second gas supply source 161 may supply an etching gas used to treat the substrate W as a process gas.

A single second gas supply source 161 may be provided to supply the process gas to the shower head unit 140. However, the present embodiment is not limited thereto. A plurality of second gas supply sources 161 may be provided to supply the process gas to the shower head unit 140.

The second gas supply line 162 connects the second gas supply source 161 and the shower head unit 140. The second gas supply line 162 transfers the process gas supplied through the second gas supply source 161 to the shower head unit 140 so that the process gas can be introduced into the housing 110.

On the other hand, when the shower head unit 140 is divided into a center zone, a middle zone, an edge zone, and the like, the second gas supply unit 160 may further include a gas distribution unit (not shown) and a gas distribution line (not shown) to supply a process gas to each region of the shower head unit 140.

The gas distribution unit distributes the process gas supplied from the second gas supply source 161 to each region of the shower head unit 140. The gas distribution unit may be connected to the second gas supply source 161 through the second gas supply line 162.

The gas distribution line connects the gas distribution unit and each region of the shower head unit 140. The gas distribution line may transfer the process gas distributed by the gas distribution unit to each region of the shower head unit 140 through this.

The liner unit 170 is also referred to as a wall liner, and is used to protect the inner surface of the housing 110 from arc discharge generated while the process gas is excited, impurities generated during the substrate treating process, and the like. The liner unit 170 may be provided in a cylindrical shape, in which the upper portion and the lower portion are opened, respectively, inside the housing 110.

The liner unit 170 may be provided adjacent to the inner wall of the housing 110. The liner unit 170 may have a support ring 171 thereon. The support ring 171 may protrude from an upper portion of the liner unit 170 in an outward direction (i.e., in the first direction 10), and may be placed on the upper end of the housing 110 to support the liner unit 170.

The baffle unit 180 serves to exhaust process-by-products of plasma, unreacted gas, and the like. The baffle unit 180 may be installed between the inner wall of the housing 110 and the substrate support unit 120.

The baffle unit 180 may be provided in an annular ring shape, and may include a plurality of through holes penetrating in the vertical direction (i.e., the third direction 30). The baffle unit 180 may control the flow of the process gas according to the number and shape of the through holes.

The upper module 190 is installed to cover the open upper portion of the housing 110. The upper module 190 may include a window member 191, an antenna member 192, and an antenna unit 193.

The window member 191 is formed to cover the upper portion of the housing 110 in order to seal the inner space of the housing 110. The window member 191 may be provided in the shape of a plate (e.g., a disk), and may be formed of an insulating material (e.g., alumina (Al₂O₃)).

The window member 191 may be formed to include a dielectric window. The window member 191 may have a hole, through which the second gas supply line 162 is inserted, and a coating film may be formed on its surface in order to suppress the generation of particles when the plasma process is performed inside the housing 110.

The antenna member 192 is installed above the window member 191, and a space of a predetermined size may be provided so that the antenna unit 193 can be disposed therein.

The antenna member 192 may be formed in a cylindrical shape with an open lower portion, and may be provided to have a diameter corresponding to that of the housing 110. The antenna member 192 may be provided to be detachably attached to the window member 191.

The antenna unit 193 functions as an upper electrode, and is equipped with a coil provided to form a closed loop. The antenna unit 193 generates a magnetic field and an electric field inside the housing 110 based on the power supplied from the upper power source 131, and functions to excite gas, which flows into the housing 110 through the shower head unit 140, into plasma.

The antenna unit 193 may be equipped with a coil in the form of a planar spiral. However, the present embodiment is not limited thereto. The structure and size of the coil may be variously changed by those skilled in the art.

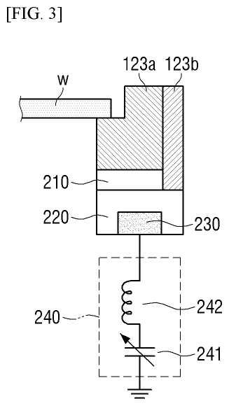

FIG. 3 is a partially enlarged view of a substrate treating system according to various embodiments of the present disclosure;

Referring to FIG. 3, the substrate treating system 100 may comprise a first ring member 210, a second ring member 220, an insert 230, and an impedance control unit 240 under the ring assemblies 123a and 123b.

The first ring member 210 is installed under the focus ring 123a. The first ring member 210 may be made of a metal material. The first ring member 210 may be made of, for example, an aluminum material.

The second ring member 220 is installed under the first ring member 210 and the insulator ring 123b. The second ring member 220 may be provided as an insulator like the insulator ring 123b.

The second ring member 220 may be provided to cover the circumference of the electro-static chuck 122. Through this, the second ring member 220 may separate the electro-static chuck 122 from the outer wall of the housing 110 and electrically insulate the focus ring 123a from modules disposed under the electro-static chuck 122.

The insert 230 is inserted into the second ring member 220. The insert 230 may be provided with a conductive material and may be connected to the impedance control unit 240. When the insert 230 is provided with a conductive material as described above, an electric field coupling effect may be induced around the second ring member 220.

When provided with a conductive material, the insert 230 may be provided with, for example, a dielectric material. However, the present embodiment is not limited thereto. The insert 230 may be provided with a metal material.

The impedance control unit 240 controls the impedance of the second ring member 220. Specifically, the impedance control unit 240 may control the impedance of the second ring member 220 by adjusting the coupling between the plasma impedance Z and the lower power source 133. Here, the lower power source 133 refers to a high frequency power source that supplies RF power to the electrodes provided on the electro-static chuck 122.

The impedance control unit 240 may control the impedance of the second ring member 220 to change the potential of the plasma sheath formed at the edge of the electro-static chuck 122. In addition, the impedance control unit 240 may also control the ions incident through the plasma sheath, and accordingly, strengthen the control of the etch rate (ER) and the etching profile of the edge of the substrate W.

The impedance control unit 240 may be installed outside the housing 110 to be electrically connected to the insert 230. The impedance control unit 240 may include, for example, a variable capacitor 241 and an inductor 242. In this case, the variable capacitor 241 and the inductor 242 may be connected in series to the insert 230 and GND, but may also be connected in parallel. In the present embodiment, the configuration of the circuit, in which the impedance control unit 240 can be implemented, is not limited thereto, and a circuit of any configuration may be provided as long as it is electrically connected to the insert 243 and controls the high frequency power coupled to the periphery of the electro-static chuck 122.

The impedance control unit 240 may adjust the degree of RF power coupling between the electro-static chuck 122 and the focus ring 123a. The impedance control unit 240 can easily control the electric field and plasma density of the edge of the electro-static chuck 122 through this, and can control the direction of incident ions through the plasma sheath formed on the upper portion of the focus ring 123a. In the present embodiment, the wear of the focus ring 123a may be reduced through the impedance control unit 240 as described above.

As described above, as the etching time using plasma increases, the ring assembly 123 is worn, so that the angle of incidence of ions may be gradually changed. In this case, the impedance control unit 240 may change the incident angle of the ions.

However, if the impedance of the second ring member 220 is controlled using the impedance control unit 240 after checking the result of the ion incident angle (SCD), efficiency may be reduced in terms of mass product.

Accordingly, in the present embodiment, the impedance control unit 240 may serve to predict the occurrence of wear of the ring assembly 123 and automatically compensate the impedance. Hereinafter, this will be described in detail.

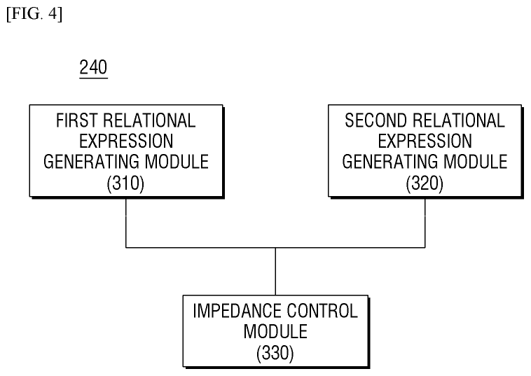

FIG. 4 is a block diagram schematically illustrating an internal configuration of an impedance control unit constituting a substrate treating system according to various embodiments of the present embodiment.

Referring to FIG. 4, the impedance control unit 240 may include a first relational expression generating module 310, a second relational expression generating module 320, and an impedance control module 330.

The first relational expression generating module 310 generates a first relational expression. The first relational expression generating module 310 may generate a first relational expression based on the correlation between an incident angle of ions (SCD) and a voltage (EBIC Vpp) measured using a circuit element (e.g., a variable capacitor 241, an inductor 242, etc.) according to an etching time using plasma.

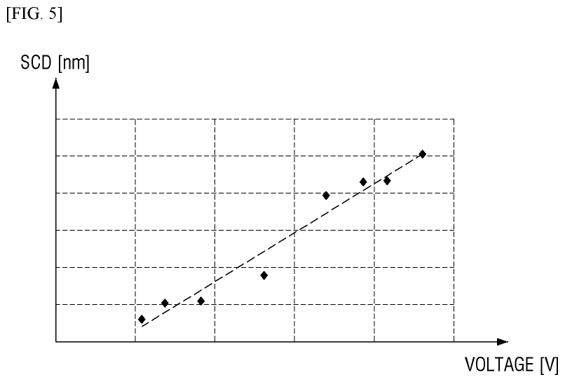

The correlation between the voltage measured using the circuit element and the incident angle of the ions may be represented, for example, as shown in FIG. 5. Referring to FIG. 5, a correlation between a voltage measured using a circuit element and an incident angle of ions may be represented as a linear function. Here, the incident angle of the ions may be proportional to the voltage measured using the circuit element. FIG. 5 is an exemplary diagram for describing the function of the first relational expression generating module constituting the impedance control unit shown in FIG. 4.

The first relational expression generating module 310 may define the first relational expression as follows based on the correlation between the voltage and the ion incident angle shown as in the example of FIG. 5.

y=ax+b

In the above, y denotes an incident angle of ions, and x denotes a voltage measured using a circuit element. Also, a denotes a first variable, and b denotes a second variable. The first variable (a) and the second variable (b) may be derived, for example, through the graph of FIG. 5.

It will be described again with reference to FIG. 4.

The second relational expression generating module 320 generates a second relational expression. The second relational expression generating module 320 may generate a second relational expression based on the correlation between the impedance (Z) and the voltage (EBIC Vpp) measured using a circuit element according to an etching time using plasma.

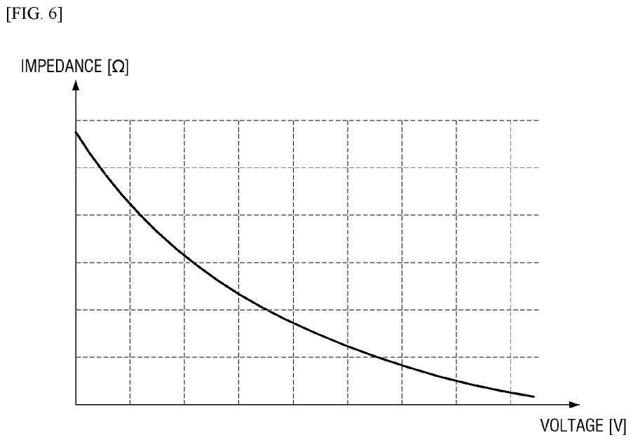

The correlation between the impedance and the voltage measured using the circuit element may be represented, for example, as shown in FIG. 6. Referring to

FIG. 6, the correlation between the impedance and the voltage measured using the circuit element may be represented as an exponential function. Here, the impedance may be inversely proportional to the voltage measured using the circuit element. FIG. 6 is an exemplary diagram for describing the function of the second relational expression generating module constituting the impedance control unit shown in FIG. 4.

The second relational expression generating module 320 may define the second relational expression as follows based on the correlation between the voltage and the impedance shown in the example of FIG. 6.

y=a^{x}+β

In the above, y means impedance, and x means a voltage measured using a circuit element. In addition, a denotes a third variable, and β denotes a fourth variable. The third variable (a) and the fourth variable (β) may be derived, for example, through the graph of FIG. 6.

It will be described again with reference to FIG. 4.

The impedance control module 330 controls the impedance of the second ring member 220. The impedance control module 330 uses the first relational expression established by the first relational expression generating module 310 and the second relational expression established by the second relational expression generating module 320 to control the impedance of the second ring member 220.

The first relational expression is generated based on the correlation between the voltage measured using the circuit element and the incident angle of the ions, and the second relational expression is generated based on the correlation between the voltage measured using the circuit element and the impedance. Accordingly, when the impedance control module 330 controls the impedance of the second ring member 220 using the first and second relational expressions, the impedance of the second ring member 220 can be controlled based on the correlation between the incident angle of the ions and the impedance.

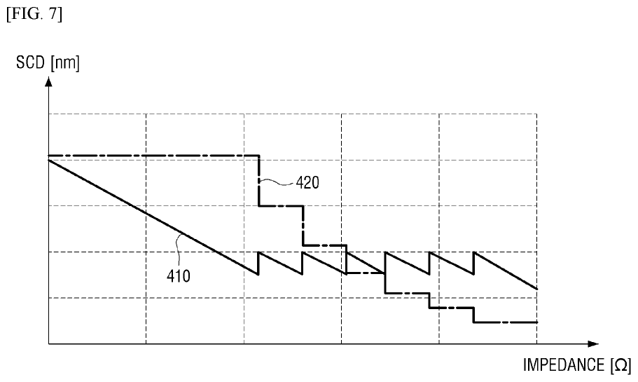

The correlation between the incident angle of the ions and the impedance may be represented, for example, as shown in FIG. 7. FIG. 7 is an exemplary view for describing the function of the impedance control module constituting the impedance control unit shown in FIG. 4. In FIG. 7, reference numeral 410 is a curve indicating a change in the incident angle of the ions according to a change in the impedance value, and reference numeral 420 is a curve indicating a change in the impedance value according to a change in the incident angle of the ions.

The first relational expression and the second relational expression may be established in advance with respect to the etching equipment and stored in the form of a lookup table (EBIC Lookup Table). In this case, the lookup table may be represented as a correlation between an incidence angle of ions and an impedance value with respect to an etching time using plasma. The impedance control module 330 may automatically control the impedance of the second ring member 220 according to an etching time using plasma by using such a lookup table.

Meanwhile, the impedance control module 330 may control the impedance of the second ring member 220 in real time by using a lookup table.

As described above, the impedance control module 330 may control the impedance of the second ring member 220 based on the correlation between the incident angle of the ions and the impedance according to the etching time using plasma.

However, the present embodiment is not limited thereto. The impedance control module 330 may also control the impedance of the second ring member 220 based on a correlation between a voltage measured using a circuit element and an incident angle of ions according to an etching time using plasma. In this case, the impedance control module 330 may control the impedance of the second ring member 220 using only the first relational expression established by the first relational expression generating module 310. That is, the impedance control module 330 may function to automatically change the incident angle of the ions.

Meanwhile, the impedance control module 330 may control the impedance of the second ring member 220 based on a correlation between a voltage measured using a circuit element and an impedance according to an etching time using plasma. In this case, the impedance control module 330 may control the impedance of the second ring member 220 using only the second relational expression established by the second relational expression generating module 320. That is, the impedance control module 330 may function to automatically change the impedance.

The first relational expression generating module 310, the second relational expression generating module 320, and the impedance control module 330 may be implemented as any one of a hardware method, a software method, and a combination of both methods in this embodiment, and when implemented as a software method, a memory, in which a program code including a first relational expression generating module 310, a second relational expression generating module 320, and the impedance control module 330 is stored, and a processor executing the program code may be included in the impedance control unit 240.

The impedance control unit 240 may automatically control the impedance of the second ring member 220 whenever a predetermined time elapses. Hereinafter, this will be described in detail.

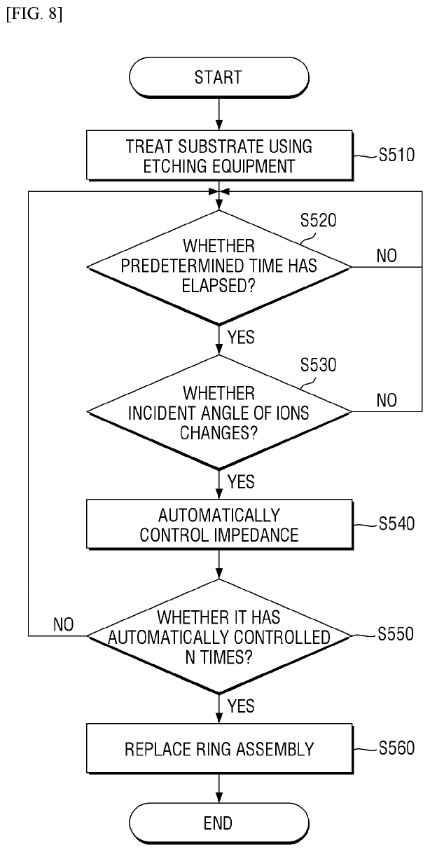

FIG. 8 is a flowchart illustrating an operation method of an impedance control unit constituting a substrate treating system according to an embodiment of the present invention. The following description refers to FIG. 8.

The impedance control unit 240 determines whether a predetermined time has elapsed from the time the substrate is started to be treated using the etching equipment (S510 and S520).

When it is determined that the predetermined time has elapsed, the impedance control unit 240 analyzes the incident angle of the ions and determines whether there is a change in the incident angle of the ions according to the plasma sheath (S530).

If it is determined that there is a change in the incident angle of ions according to the plasma sheath, the impedance control unit 240 automatically/real-time controls the impedance of the second ring member 220 using a lookup table (S540).

In this case, the lookup table may be represented as a correlation between an incident angle of ions and an impedance value with respect to an etching time using plasma. However, the present embodiment is not limited thereto. The lookup table may represent the correlation between the incident angle of ions and the voltage measured using the circuit element with respect to the etching time using the plasma, or may represent the correlation between the voltage measured using the circuit element and the impedance with respect to the etching time using the plasma.

On the other hand, if it is determined that a predetermined time has elapsed, the impedance control unit 240 may automatically/real-time control the impedance of the second ring member 220 by using a lookup table without analyzing the incident angle of the ions.

The impedance control unit 240 may repeatedly perform steps S520 to S540 until the ring assembly 123 installed in the etching equipment is replaced. The impedance control unit 240 may repeatedly perform steps S520 to S540 until, for example, the impedance of the second ring member 220 is automatically controlled N times (S550). Here, N means a natural number greater than or equal to 1.

On the other hand, when the impedance of the second ring member 220 is automatically controlled N times, the impedance control unit 240 may request replacement of the ring assembly 123 installed in the etching equipment to a terminal accessed by the administrator (S560).

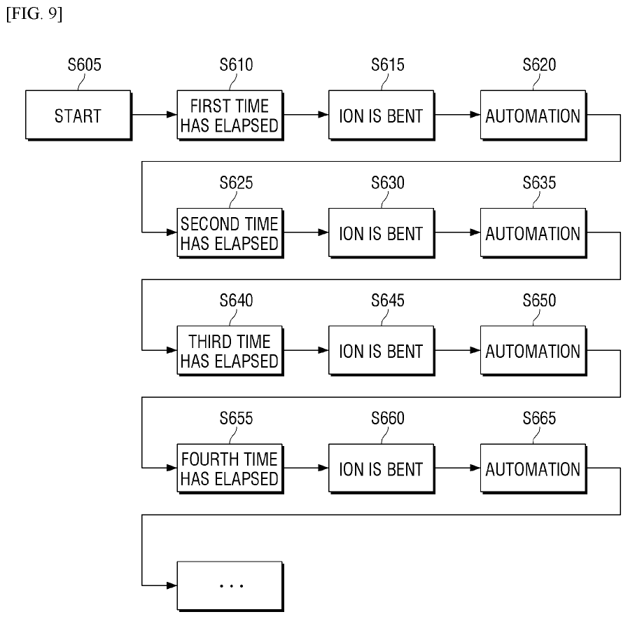

Meanwhile, whenever the impedance of the second ring member 220 is automatically controlled, the predetermined time may be shortened. In this case, the impedance control unit 240 may operate according to the sequence shown in FIG. 9. FIG. 9 is an exemplary diagram illustrating an operation method of an impedance control unit constituting a substrate treating system according to an embodiment of the present invention. The following description refers to FIG. 9.

After the etching equipment is first used (S605), the impedance control unit 240 determines whether a first time has elapsed (S610). The first time may be, for example, 200 hours (200 h).

When it is determined that the first time has elapsed, the impedance control unit 240 analyzes the incident angle of the ions and determines whether there is a change in the incident angle of the ions according to the plasma sheath (S615).

If it is determined that there is a change in the incident angle of the ions according to the plasma sheath, the impedance control unit 240 automatically/real-time controls the impedance of the second ring member 220 using a lookup table (S620).

After the impedance of the second ring member 220 is automatically controlled once, the impedance control unit 240 determines whether a second time has elapsed (S625). The second time may have a smaller value than the first time. The second time may be, for example, 50 hours (50 h).

When it is determined that the second time has elapsed, the impedance control unit 240 analyzes the incident angle of the ions, and determines whether there is a change in the incident angle of the ions according to the plasma sheath (S630).

If it is determined that there is a change in the incident angle of the ions according to the plasma sheath, the impedance control unit 240 automatically/real-time controls the impedance of the second ring member 220 using a lookup table (S635).

After the impedance of the second ring member 220 is automatically controlled twice, the impedance control unit 240 determines whether a third time has elapsed (S640). The third time may have a smaller value than the second time. The second time may be, for example, 40 hours (40 h).

If it is determined that the third time has elapsed, the impedance control unit 240 analyzes the incident angle of the ions and determines whether there is a change in the incident angle of the ions according to the plasma sheath (S645).

If it is determined that there is a change in the incident angle of ions according to the plasma sheath, the impedance control unit 240 automatically/real-time controls the impedance of the second ring member 220 using a lookup table (S650).

After the impedance of the second ring member 220 is automatically controlled three times, the impedance control unit 240 determines whether a fourth time has elapsed (S655). The fourth time may have a smaller value than the third time. The fourth time may be, for example, 30 hours (30 h).

When it is determined that the fourth time has elapsed, the impedance control unit 240 analyzes the incident angle of the ions and determines whether there is a change in the incident angle of the ions according to the plasma sheath (S660).

If it is determined that there is a change in the incident angle of ions according to the plasma sheath, the impedance control unit 240 automatically/real-time controls the impedance of the second ring member 220 using a lookup table (S665).

Although the embodiments of the present invention have been described with reference to the above and the accompanying drawings, those of ordinary skill in the art, to which the present invention pertains, can understand that the present invention may be practiced in other specific forms without changing its technical spirit or essential features. Therefore, it should be understood that the embodiments described above are illustrative in all respects and not limiting.

What is claimed is:

1. A system for treating a substrate comprising:
a housing for providing a space for treating a substrate;
a substrate support member installed inside the housing and for supporting the substrate;
a plasma generating unit for generating plasma inside the housing;
a ring assembly disposed in circumference of the substrate; and
an impedance control unit for controlling an impedance around the ring assembly and automatically compensating the impedance by predicting occurrence of wear of the ring assembly.

2. The system of claim 1, wherein the impedance control unit controls the impedance based on at least one of a first correlation between a measured voltage around the ring assembly and an ion incident angle around the ring assembly according to a substrate treating time, a second correlation between the measured voltage and the impedance, and a third correlation between the ion incident angle and the impedance.

3. The system of claim 2, wherein the impedance control unit derives the third correlation based on the first correlation and the second correlation.

4. The system of claim 2, wherein the impedance control unit generates a first relational expression for calculating the ion incidence angle by calculating the measured voltage, a first variable, and a second variable when the impedance is controlled based on the first correlation.

5. The system of claim 4, wherein the impedance control unit calculates a value proportional to the measured voltage as the ion incident angle by using the first relational expression.

6. The system of claim 4, wherein the first relational expression is a linear function.

7. The system of claim 2, wherein the impedance control unit generates a second relational expression for calculating the impedance by calculating the measured voltage, a third variable, and a fourth variable when the impedance is controlled based on the second correlation.

8. The system of claim 7, wherein the impedance control unit calculates a value inversely proportional to the measured voltage as the impedance by using the second relational expression.

9. The system of claim 7, wherein the second relational expression is an exponential function.

10. The system of claim 1, wherein the impedance control unit controls the impedance by using a lookup table generated based on a substrate treating time.

11. The system of claim 10, wherein the impedance control unit generates the lookup table based on at least two components of a measured voltage around the ring assembly, an ion incident angle around the ring assembly, and the impedance according to the substrate treating time.

12. The system of claim 1, wherein the impedance control unit repeatedly controls the impedance based on a comparison result between a substrate treating time and a reference time.

13. The system of claim 12, wherein a reference time used for a first impedance control is longer than a reference time used for a second impedance control performed after the first impedance control.

14. The system of claim 1 further comprises,
a first ring member including a metal component and installed under the ring assembly;
a second ring member including an insulator component and installed under the first ring member and the ring assembly; and
an insert including a conductive material and inserted into the inside of the second ring member,
wherein the impedance control unit is electrically connected to the insert.

15. A system for treating a substrate comprising:
a housing for providing a space for treating a substrate;
a substrate support member installed inside the housing and for supporting the substrate;
a plasma generating unit for generating plasma inside the housing;
a ring assembly disposed in circumference of the substrate; and
an impedance control unit for controlling an impedance around the ring assembly, and automatically compensating the impedance based on at least one of a first correlation between a measured voltage around the ring assembly and an ion incident angle around the ring assembly according to a substrate treating time, a second correlation between the measured voltage and the impedance, and a third correlation between the ion incident angle and the impedance.

16. An apparatus for controlling an impedance, wherein the apparatus controls an impedance around a ring assembly disposed in circumference of a substrate when treating the substrate, comprising:
a first relational expression generating module for generating a first relational expression based on a first correlation between a measured voltage around the ring assembly and an ion incident angle around the ring assembly according to a substrate treating time;
a second relational expression generating module for generating a second relational expression based on a second correlation between the measured voltage and the impedance; and
an impedance control module for controlling the impedance based on the first relational expression and the second relational expression.

17. The apparatus of claim 16, wherein the impedance control module automatically compensates the impedance by predicting occurrence of wear of the ring assembly.

18. The apparatus of claim 16, wherein the first relational expression generating module generates the first relational expression to calculate the ion incident angle by calculating the measured voltage, a first variable, and a second variable.

19. The apparatus of claim 16, wherein the second relational expression generating module generates the second relational expression to calculate the impedance by calculating the measured voltage, a third variable, and a fourth variable.

20. The apparatus of claim 16, wherein the impedance control module controls the impedance by using a lookup table generated based on the first relational expression and the second relational expression.
